(19) United States
(12) Patent Application Publication
(10) Pub. No.: US 2021/0150649 A1
(43) Pub. Date: May 20, 2021

(54) REAL ESTATE AUGMENTED REALITY SYSTEM

(71) Applicant: Carrier Corporation, Palm Beach Gardens, FL (US)

(72) Inventors: Gaurav Holey, Nagpur (IN); Anil Thirumalasetti, Hyderabad (IN); Syed Abdul Hameed, Hyderabad (IN); Rajinikanth Pusala, Hyderabad (IN)

(73) Assignee: Carrier Corporation, Palm Beach Gardens, FL (US)

(21) Appl. No.: 17/254,964

(22) PCT Filed: Jun. 13, 2019
(86) PCT No.: PCT/US2019/036911

§ 371 Date: Dec. 22, 2020

(30) Foreign Application Priority Data
Aug. 6, 2018 (IN) 201811029432

(51) Int. Cl. G06Q 50/16; G06T 19/00; G06F 30/13; G03H 1/22

(52) U.S. Cl. CPC G06Q 50/16; G03H 1/2294; G06F 30/13; G06T 19/006

(57) ABSTRACT

A method for providing an augmented reality view includes displaying a virtual object within a subject real estate property by a holographic projector, the virtual object associated with a user.

### BACKGROUND

The present disclosure relates generally to a system to facilitate communication for real estate transactions, and more particularly, to a system to project augmented reality views during a home showing.

In the real estate industry, a prospective property buyer must often mentally imagine potential improvements and furnishings. This can be frustrating to agents and sellers who are otherwise only minimally able to place the subject property in the best light to the prospective property buyer.

### SUMMARY

A method for providing an augmented reality view according to one disclosed non-limiting embodiment of the present disclosure includes displaying a virtual object of an interior design within a subject real estate property by a holographic projector, the virtual object associated with a user.

A further aspect of the present disclosure includes that the virtual object comprises a three-dimensional representation of the interior design for the subject property.

A further aspect of the present disclosure includes that the interior design is selected from one of a multiple of interior designs stored on a server.

A further aspect of the present disclosure includes that the associating the virtual object with the user is performed within an augmented reality application.

A further aspect of the present disclosure includes that the displaying step comprises displaying the virtual object as a three dimensional rendering to provide an augmented reality view within the subject real estate property.

A further aspect of the present disclosure includes that the displaying step comprises displaying a lighting scheme for the virtual object based on a desired time of day.

An augmented reality system, according to one disclosed non-limiting embodiment of the present disclosure, includes a server to store virtual object data in a database; and a holographic projector in communication with the server to display the virtual object data within a subject real estate property to provide an augmented reality view within the subject real estate property.

A further aspect of the present disclosure includes that the holographic projector displays a lighting scheme for the virtual object based on a desired time of day.

A further aspect of the present disclosure includes that the virtual object data of the augmented reality view is associated with a user within an augmented reality application.

The foregoing features and elements may be combined in various combinations without exclusivity, unless expressly indicated otherwise. These features and elements as well as the operation thereof will become more apparent in light of the following description and the accompanying drawings. It should be understood, however, the following description and drawings are intended to be exemplary in nature and non-limiting.

### BRIEF DESCRIPTION OF THE DRAWINGS

Various features will become apparent to those skilled in the art from the following detailed description of the disclosed non-limiting embodiment. The drawings that accompany the detailed description can be briefly described as follows:

FIG. 1 is a general schematic system diagram of a real estate feedback application system.

FIG. 2 is a schematic diagram of a mobile device.

FIG. 3 is a flowchart of a method to provide feedback for real estate, with the system of FIG. 1.

FIG. 4 is a schematic view of an augmented reality system.

FIG. 5 is a flowchart illustrating operation of the augmented reality system.

FIG. 6 is a schematic view illustrating operation of the augmented reality system.

FIG. 7 is a flowchart illustrating operation of the augmented reality system from the perspective of a user.

### DETAILED DESCRIPTION

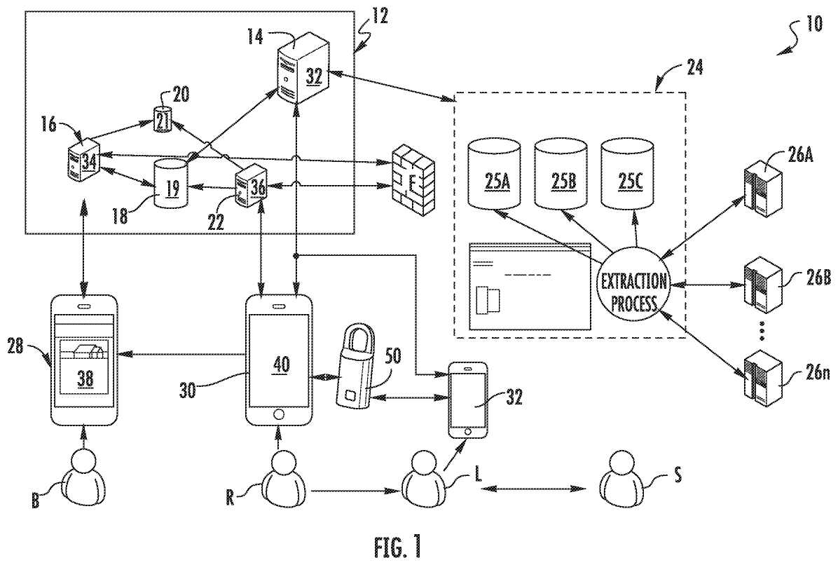

FIG. 1 schematically illustrates a system 10 to facilitate communication for real estate transactions. A property buyer “B” is typically represented by a showing agent “R” while a property seller “S” of a subject property “H” is typically represented by a listing agent “L”. The listing agent “L” typically communicates with the buyer “B” only indirectly, such as by communication with the showing agent “R” who then communicates with the buyer “B”. Although only particular agents are referred to in the illustrated embodiments to provide perspective, the functions of each may be otherwise assigned or rearranged. For example, the listing agent “L” may be a senior person in an agency who utilizes a seller's assistant. The showing agent “R” may similarly utilize a showing assistant. As is discussed below, the prospective buyer “B” may wish to obtain input from third parties “T” such as family, friends, and/or others.

The system 10 to facilitate communication for real estate transactions can include a subsystem 12 that may be controlled by a single owner. The subsystem 12 can include a listing recommendation server 14, a buyer server 16, a buyer storage system 18, a log storage system 20, and an electronic key server 22. The listing recommendation server 14 communicates with the buyer storage system 18, the log storage system 20, and a storage system 24. The buyer storage system 18 includes a database 19 that stores, for example, feedback created by the buyer “B” (e.g., buyer feedback, third party feedback, etc.). The log storage system 20 includes a database 21 that collects activity data associated with the property showings.

The storage system 24 may include, but not be limited to, a database for managing key holders 25A, a security database 25B that hosts security protocols, and a listing database 25C that stores extracted property data from external databases 26A, 26B, 26n. The storage system 24 communicates with the external databases 26A-26n such as the Real Estate Transaction Standard (RETS) framework that stores Multiple Listing Service (MLS) data. Communication between the various servers may include internet protocols or the like. The MLS data may include information such as number of bedrooms, number of bathrooms, price of listing, etc. RETS is a framework that can be adopted by computer systems to receive data from the MLS servers, as well as those of other real estate systems provided they also have software installed designed to communicate using the RETS framework. The national association of realtors refers to RETS as a “common language”.

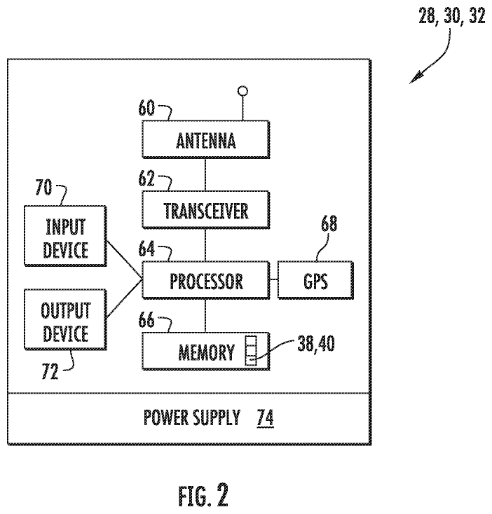

A multiple of mobile devices 28, 30, 32 (also shown in FIG. 2), may communicate with the subsystem 12. For example, the mobile devices 28, 30, 32, may be a smartphone, tablet, or other mobile device of the respective user. The mobile device 28 is used by the potential buyer “B”, the mobile device 30 is used by the showing agent “R”, and the mobile device 32 is used by the listing agent “L”. Various other mobile devices may also be in communication with the subsystem 12 either directly or through communication with the mobile devices 28, 30, 32, as an intermediary.

Information is accessible by the listing agent “L” through the subsystem 12 so that the listing agent “L” can, for example, generate reports for their seller “S”, send updates about a particular listing to showing agents “R”, or provide feedback from a buyer “B” to their seller “S”. The subsystem 12 may also obtain information from the RETS framework that stores MLS data. The subsystem 12 may also obtain information generated by an electronic key box 50 that occurs as a consequence of the showing, such as number of times shown, time spent at the subject property for each showing, return showings, etc. The subsystem 12 may also be used by the listing agents “L” to receive automatic notification (e.g., email notices) when a showing occurs at their listings. The subsystem 12 may also be used by the buyer “B” as a repository for information (e.g., details of each property the buyer has viewed, feedback on the properties, etc.). The seller “S” can also receive feedback from the buyer “B” either directly from the subsystem 12, or through communications with the listing agent “L” who communicates with the subsystem 12.

The listing recommendation server 14 hosts, for example, at least an analytics software application that compiles and runs analytics against buyer ratings and MLS listing data from the storage system 24. The buyer server 16 hosts a buyer application program interface (API) 34, and the electronic key server 22 hosts an electronic key API 36. An application program interface (API) may include a set of routines, protocols, and/or tools for building software applications. The API specifies how software components should interact. APIs are used when programming graphical user interface (GUI) components. A server-side web API is a programmatic interface with one or more publicly exposed endpoints to a defined request-response message system.

The listing recommendation server 14 may communicate with a real estate application 38 on the mobile device 28 through the buyer API 34. An agent application 40 on the mobile device 30 may communicate with the listing recommendation server 14 and the electronic key server 22. The buyer API 34 and the electronic key API 36 may also communicate with other external systems through a firewall “F”.

The real estate application 38 communicates with the buyer storage system 18 through the buyer API 34 which then stores the feedback, ratings, and notes taken by the property buyer in the database 19 of the buyer storage system 18. The real estate application 38 may be a mobile application on the mobile device 28 that may be used by the buyer “B” to rate the properties they have seen.

The agent application 40 may be a mobile application on the mobile device 30 that may be used by the showing agent “R” to access the electronic key boxes 50 via a short distance communication standard (e.g., Bluetooth). Alternatively, or in addition, the electronic key boxes 50 may be connected (e.g., cellular) directly to the listing recommendation server 14. The electronic key API 36 of the electronic key server 22 communicates with the agent application 40 to sync activity information from the electronic key boxes 50 to the electronic key API 36 (e.g., accessed key boxes, update the count of proprietary keys generated for that particular property, create a timestamp indicating that lockbox is opened), and to show notifications (e.g., to an associated showing agent “R”).

With reference to FIG. 2, each mobile device 28, 30, 32, generally includes a mobile device antenna 60, a mobile device transceiver 62, a mobile device processor 64, a mobile device memory 66, a GPS module 68, an input device 70, a display 72, and a mobile device power supply 74. The mobile device processor 64 may be any type of microprocessor having desired performance characteristics. The mobile device memory 66 may include any type of computer readable medium that stores the data and executable instructions described herein below. The executable instructions may be stored or organized in any manner and at any level of abstraction, such as in connection with one or more applications, processes, routines, procedures, methods, etc. The mobile device transceiver 62 is a transceiver of a type corresponding to the transceiver 62 and the mobile device antenna 60 is a corresponding antenna.

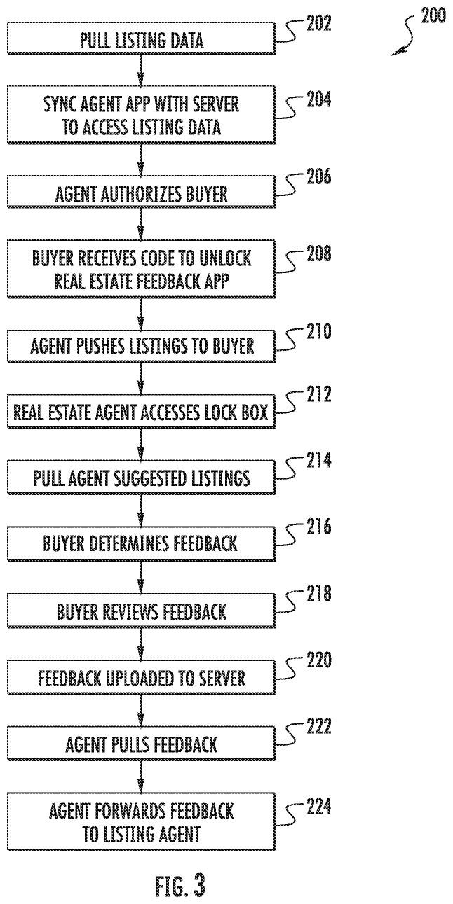

With reference to FIG. 3, a method 200 for operation of the system 10 is disclosed in terms of functional block diagrams. The functions are programmed software routines capable of execution in various microprocessor-based electronics control embodiments and represented herein as block diagrams.

Initially, the owner of the subsystem 12 may have agreements with MLS to selectively extract (202) data such as MLS data from the external data servers 26A-26n (FIG. 1) through the listing recommendation server 14. Next, the agent application 40 syncs (204) with the listing recommendation server 14 and pulls MLS data for desired property listings of interest to the buyer “B” as, for example, selected by the showing agent “R”. This may be performed through an automated sync through the agent application 40. The showing agent “R” may also perform a manual sync to obtain the MLS data.

Through the agent application 40, the showing agent “R” can then authorize (206) the prospective property buyer “B” to access the desired property listings of interest to the buyer “B”. Through the agent application 40, the showing agent “R” may, for example, authorize the buyer “B” through input of buyer identification information (e.g., buyer name and email address.) The buyer identification information is then communicated to the listing recommendation server 14 which then provides the buyer “B” (e.g., via email to provide a link to an app store) with a code to unlock (208) the real estate application 38. The buyer “B” is then authorized to download the real estate application 38 and the desired property listings of interest to the buyer “B” to maintain the value of the showing agent “R” in the real estate transaction.

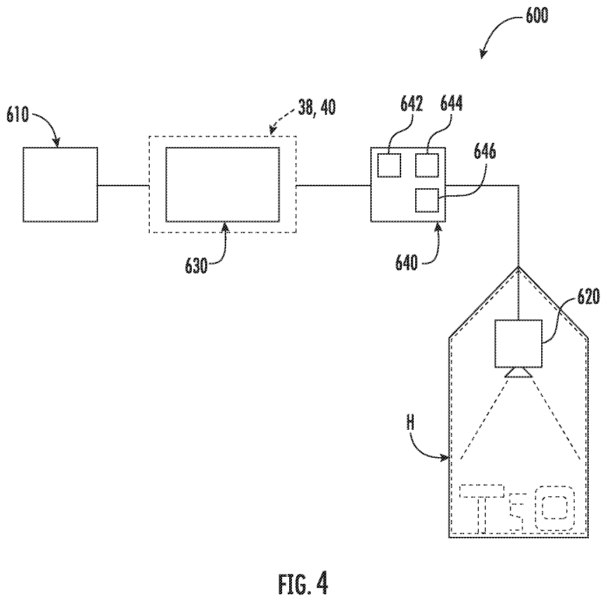

Through the agent application 40, the showing agent “R” can continue to push (210) property listings to the real estate application 38. Access may be provided for one or more properties by a showing code, or other information that unlocks one or more modules in the real estate application 38. The modules may include features or other aspects that are particular tailored to certain parties in the real estate transaction. The showing agent “R” is able to selectively push the desired property listings of interest to the buyer “B” (one example property listing illustrated by screenshot “P”; FIG. 4) through the subsystem 12 to be viewable within the real estate application 38. The showing agent “R” also uses the agent application 40 to operate the electronic key box 50 to access the property for showing to the buyer “B”.

Next, during the showing, feedback may be entered into the real estate feedback application 500 by the buyer “B” for the property (216). The feedback may include any data associated with the properties that may, for example, facilitate reviewing and comparing properties. The real estate feedback application 500 may be a module of the real estate application 38, and/or other application. As the buyer generates feedback about the property, the real estate feedback application 500 may also upload the feedback to the buyer storage system 18 via the buyer API 34 (220; FIG. 1). Once the showing is complete, the buyer “B” can choose to selectively share the feedback with their showing agent “R” via the real estate feedback application 500 which, in response, authorizes the listing recommendation server 14 to release the feedback from the buyer storage system 18. The agent application 40 then syncs with the listing recommendation server 14 and downloads the feedback (222). The showing agent “R” is then able to review the feedback on the agent application 40. Through the agent application 40, the showing agent “R” can communicate the feedback to the listing agent “L” (224).

With reference to FIG. 4, an augmented reality system 600 may be included with the system 10 for use by the showing agent “R”, the listing agent “S”, and the prospective property buyer “B”. The augmented reality system 600 generally includes an input device 610, a holographic projector 620, an augmented reality application 630, and a server 640.

The augmented reality application 630 may be a sub-application within the real estate application 38 (FIG. 1), the agent application 40 (FIG. 1), an application associated therewith, or a stand-alone application that is in communication with the system 10. The augmented reality application 630 may utilize one or more various augmented reality processes such as simultaneous localization and mapping (SLAM), geo-marking, or others. Examples of such are augmented reality kits, namely the Apple AR kit, or Google Tango. These augmented reality kits perform environment mapping to determine the three-dimensional space of the subject real estate property “H” as the device is moved, and allow the augmented reality application 630 to capture data from one or more of the on-board sensors.

The input device 610 may be, for example, the agent mobile device 28 (FIG. 1), computer, web interface, or other input accessible by the prospective property buyer “B”, the showing agent “R”, and/or the listing agent “S”. The input device 610 utilizes the augmented reality application 630. The augmented reality application 630 may be a cloud-based web application that transforms an interior design into 3D holographic graphics for the subject property. The augmented reality application 630 may offer templates and/or other 3D virtual images that are selectable and positionable within the three-dimensional environment data for the respective subject real estate property.

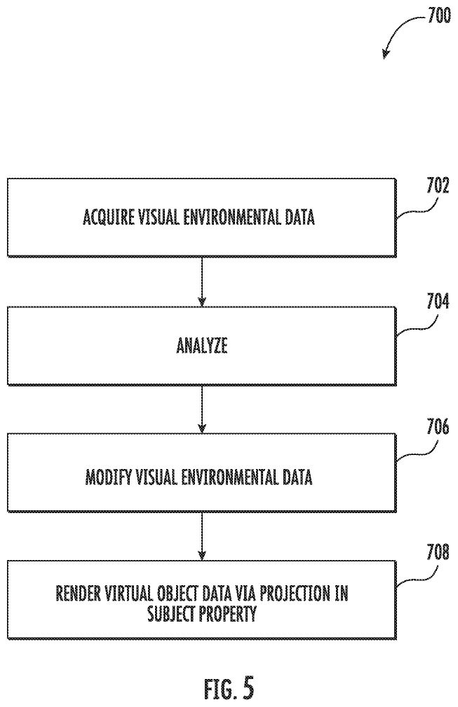

The holographic projector 620 may be, for example, the Mirage WU-L WUXGA DLP 3D projector manufactured by Christie®, a wholly-owned subsidiary of Ushio, Inc., of Japan, that utilizes the augmented reality application 630. For example, an image projected from the rear of bounce screen and in between the foils forms a vertical image. The input device 610 may include a camera, a gyroscope, an accelerometer, and/or other sensor to facilitate operation of a method 700 (FIG. 5) for providing an augmented reality view of the subject real estate property “H” via the augmented reality application 630.

The server 640 may be a subdivision of the listing recommendation server 14, a stand-alone server in the system 10 (FIG. 1). The server 640 may be a physical or cloud-based server that can run on the same machine or on different machines on the same network of the system architecture. The server 640 houses, in this embodiment, a database 642 of three-dimensional environment data for each of the respective subject real estate properties. The server 640 also houses, in this embodiment, a database 644 of virtual images such as furniture, appliances, fixtures, lighting schemes, etc. for selection by, for example, the showing agent “R” to be presented to a particular prospective property buyer “B”. That is, the showing agent “R” can configure a particular property for a particular prospective property buyer “B” to present the property in the best light for each prospective property buyer “B”. Based on the request received from the augmented reality application 630, the selected virtual images are retrieved from the server 640 and communicated to the holographic projector 620.

With reference to FIG. 5, the method 700 for providing an augmented reality view for a subject real estate property is disclosed in terms of functional block diagrams. The functions are programmed software routines and executable instructions capable of execution in various microprocessor-based electronics control embodiments and represented herein as block diagrams.

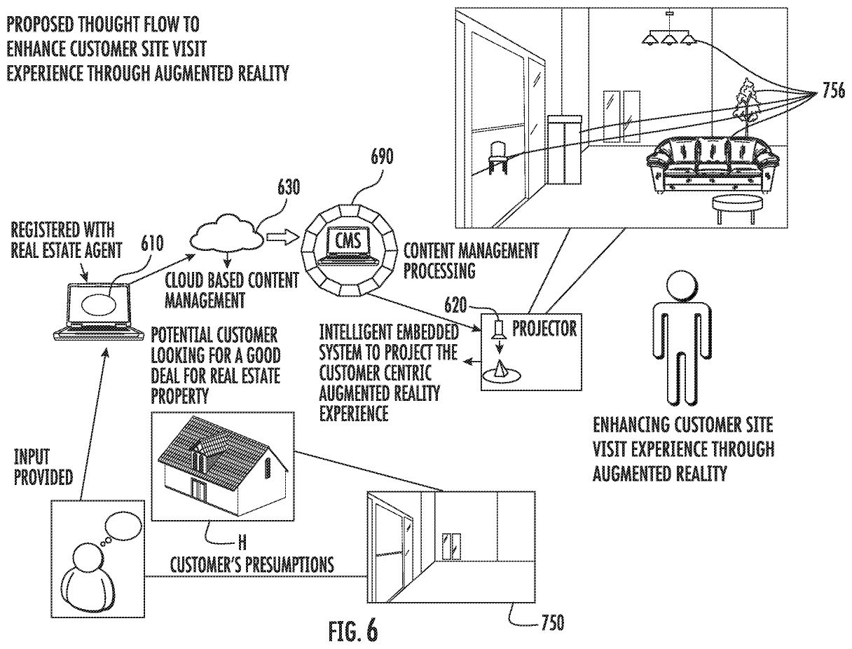

Initially, visual environment data of the subject real estate property “H” may be acquired (702) with the input device 610 or other source for use by the augmented reality application 630. The visual environment data may be obtained by the showing agent “R”, the buyer “B”, or some other user. Sensors of the input device 610 such as one or more cameras, GPS modules, and/or other sensors, which are typically standard on board a mobile device such as a smart phone, may be utilized by the augmented reality application 630 to collect the visual environment data (750; FIG. 6) regarding the subject property. Based on known likes and dislikes of the buyer “B”, the showing agent “R” can include or modify the virtual interior design in the virtual space formed by the three-dimensional space of the subject real estate property “H”. The request may be received by the augmented reality application 630 and be modified with virtual objects that can be re-deployed to the cloud so that the buyer “B” can view with updated changes.

Next, the visual environment data is analyzed (704) by the augmented reality application 630 to determine the three-dimensional space of the subject real estate property “H”.

Next, the captured visual environment data can be modified (706) by including virtual objects (756; FIG. 6) into the three-dimensional space of the subject real estate property at a desired location or locations. The visual environment data may be modified with the inclusion of virtual object data within the three-dimensional space at desired locations via the augmented reality application 630. The virtual images may be created by, for example, 3D software such as AutoCad3D, StudioMax, Cinema4D, etc., that is then stored in the database 644 of virtual images for access by the augmented reality application 630. Alternatively, other three-dimensional virtual images can be generated and stored in the database 644 of virtual images for later use.

The augmented reality application 630 is then utilized by, for example, the showing agent “R” to select and position the virtual object into the three-dimensional space of the subject real estate property at a desired location, for example, a particular table is selected from the database 644 of virtual images then placed in a particular location in the subject real estate property to provide a particular interior design. The desired locations may be identified by a geo-marker that positions the virtual objects in the three-dimensional space of the subject real estate property.

Then, the virtual object data (756; FIG. 6) from the server 640 is rendered (708) by the holographic projector 620 as 3D holograms or other displays. Based on the request received from the augmented reality application 630, the virtual images are retrieved from the server 640 and sent to the augmented reality application 630 for display by the holographic projector 620. The virtual object is displayed within the three-dimensional space of the subject real estate property.

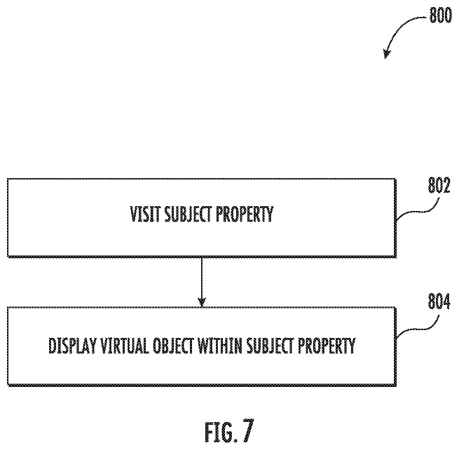

With reference to FIG. 7, a method 800 for providing an augmented reality view for a real estate property via the augmented reality application 630 from the perspective of the buyer “B” is disclosed in terms of functional block diagrams. The functions are programmed software routines and instructions capable of execution in various microprocessor-based electronics control embodiments and represented herein as block diagrams.

Initially, the showing agent “R”, and the buyer “B”, may register with the augmented reality application 630. The showing agent “R” then typically escorts the buyer “B” for a showing or visit of subject property (802). Next, during the showing, the augmented reality application 630 will retrieve the virtual object data from the server 640 and display (804) the virtual objects within the subject real estate property that are associated with a user. In embodiments, the virtual objects can be modified to a particular lighting scheme, a particular time of day, or other modification that further refines the virtual objects.

The augmented reality application 630 can increase an agent's chance of selling the subject property as the virtual objects rendered within the subject real estate property can be tailored to particular buyers “B”. That is, the subject property can be selectively presented in accords with the taste of the particular buyer “B”. Further, third parties such as movers can later arrange the actual interior of the subject property exactly as desired by the buyer “B”.

The elements described and depicted herein, including in flow charts and block diagrams throughout the figures imply logical boundaries between the elements. However, according to software or hardware engineering practices, the depicted elements and the functions thereof may be implemented on machines through computer executable media having a processor capable of executing program instructions stored thereon as a monolithic software structure, as standalone software modules, or as modules that employ external routines, code, services, and so forth, or any combination of these, and all such implementations may be within the scope of the present disclosure.

The use of the terms “a”, “an”, “the”, and similar references in the context of description (especially in the context of the following claims) are to be construed to cover both the singular and the plural, unless otherwise indicated herein or specifically contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other.

Although the different non-limiting embodiments have specific illustrated components, the embodiments of this invention are not limited to those particular combinations. It is possible to use some of the components or features from any of the non-limiting embodiments in combination with features or components from any of the other non-limiting embodiments.

It should be appreciated that like reference numerals identify corresponding or similar elements throughout the several drawings. It should also be appreciated that although a particular component arrangement is disclosed in the illustrated embodiment, other arrangements will benefit herefrom.

Although particular sequences are shown, described, and claimed, it should be understood that steps may be performed in any order, separated or combined unless otherwise indicated and will still benefit from the present disclosure.

The foregoing description is exemplary rather than defined by the limitations within. Various non-limiting embodiments are disclosed herein, however, one of ordinary skill in the art would recognize that various modifications and variations in light of the above teachings will fall within the scope of the appended claims. It is therefore to be understood that within the scope of the appended claims, the disclosure may be practiced other than as specifically described. For that reason, the appended claims should be studied to determine true scope and content.

What is claimed is:

1. A method for providing an augmented reality view, comprising:
displaying a virtual object of an interior design within a subject real estate property by a holographic projector, the virtual object associated with a user.

2. The method as recited in claim 1, wherein the virtual object comprises a three-dimensional representation of the interior design for the subject property.

3. The method as recited in claim 2, wherein the interior design is selected from one of a multiple of interior designs stored on a server.

4. The method as recited in claim 1, wherein associating the virtual object with the user is performed within an augmented reality application.

5. The method as recited in claim 1, wherein the displaying step comprises displaying the virtual object as a three-dimensional rendering to provide an augmented reality view within the subject real estate property.

6. The method as recited in claim 1, wherein the displaying step comprises displaying a lighting scheme for the virtual object based on a desired time of day.

7. An augmented reality system, comprising:
a server to store virtual object data in a database; and
a holographic projector in communication with the server to display the virtual object data within a subject real estate property to provide an augmented reality view within the subject real estate property.

8. The system as recited in claim 7, wherein the holographic projector displays a lighting scheme for the virtual object based on a desired time of day.

9. The system as recited in claim 7, wherein the virtual object data of the augmented reality view is associated with a user within an augmented reality application.
